(19) United States
(12) Patent Application Publication
(10) Pub. No.: US 2009/0290406 A1
(43) Pub. Date: Nov. 26, 2009

(54) Low loading pad design for STT MRAM or other short pulse signal transmission

(75) Inventors: William Xia, San Diego, CA (US); Seung H. Kang, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/125,113

(22) Filed: May 22, 2008

(51) Int. Cl. G11C 11/02; H01L 21/00

(52) U.S. Cl. 365/158; 438/3; 257/E21.001

(57) ABSTRACT

A low loading pad for a Spin Transfer Torque Magnetoresistive Random Access Memory (STT-MRAM) bit cell array is provided. The low loading pad includes a plurality of hollow-shaped lower metal layers and a top metal layer formed on an uppermost layer of the plurality of hollow-shaped lower metal layers.

### FIELD OF DISCLOSURE

Exemplary embodiments of the invention are directed to structural designs of low loading pads for Magnetoresistive Random Access Memory (MRAM) bit cells. More particularly, embodiments of the invention are related to structural designs of low loading pads for Spin Transfer Torque Magnetoresistive Random Access Memory (STT-MRAM) bit cells.

### BACKGROUND

Magnetoresistive Random Access Memory (MRAM) is a non-volatile memory technology that uses magnetic elements. For example, Spin Transfer Torque Magnetoresistive Random Access Memory (STT-MRAM) uses electrons that become spin-polarized as the electrons pass through a thin film (spin filter). STT-MRAM is also known as Spin Transfer Torque RAM (STT-RAM), Spin Torque Transfer Magnetization Switching RAM (Spin-RAM), and Spin Momentum Transfer (SMT-RAM).

Referring to FIG. 1, a diagram of a conventional STT-MRAM cell 100 is illustrated. The STT-MRAM bit cell 100 includes magnetic tunnel junction (MTJ) storage element 105, transistor 110, bit line 120 and word line 130. The MTJ storage element is formed, for example, from a pinned layer and a free layer, each of which can hold a magnetic field, separated by an insulating (tunnel barrier) layer as illustrated in FIG. 1. The STT-MRAM bit cell 100 also includes a source line 140, sense amplifier 150, read/write circuitry 160 and bit line reference 170. Those skilled in the art will appreciate the operation and construction of the memory cell 100 is known in the art. Additional details are provided, for example, in M. Hosomi, et al., A Novel Nonvolatile Memory with Spin Transfer Torque Magnetoresistive Magnetization Switching: Spin-RAM, proceedings of IEDM conference (2005), which is incorporated herein by reference in its entirety.

Conventionally, a pad is used to connect, for example, the source line 140 of the STT-MRAM cell 100 to the lower portion of the transistor 110, or to connect the transistor 110 to the word lines 130, etc. Conventional pad designs use large metal grid layers (arrays) such as slotted designs in which alternating layers run perpendicular to each other, or large metal plates (e.g., full metal plates) which cover the entire pad area. The conventional pad designs typically include a large amount of metal, which leads to large capacitance from the probing pads. The conventional pads having such large amounts of parasitic capacitance can lead to signal distortion and/or to signal extinguishing, particularly for short pulse signals or high frequency signals.

### SUMMARY

Exemplary embodiments of the invention are directed to structural designs of low loading pads for Magnetoresistive Random Access Memory (MRAM) bit cells. More particularly, embodiments of the invention are related to structural designs of low loading pads for Spin Transfer Torque Magnetoresistive Random Access Memory (STT-MRAM) bit cells.

Embodiments of the present invention are directed to pad designs with reduced parasitic capacitance characteristics. For example, an embodiment of a pad design reduces the capacitance from the metal layers of the pad by removing a portion (e.g., a majority) of one or more of the lower metal layers (e.g., metal layers M1-M6) to reduce the effective area of one or more of the lower metal layers of the pad, for example, of a STT-MRAM bit cell. More particularly, an embodiment of a pad design reduces the capacitance from the metal layers of the pad by removing a center or central portion of one or more of the lower metal layers (e.g., metal layers M1-M6) to reduce the effective area of one or more of the lower metal layers of the pad, for example, of a STT-MRAM bit cell. By maintaining the edge or perimeter portion of the lower metal layers (i.e., by forming hollow-shaped lower metal layers), the novel pad design permits wire bounding at any location around the perimeter of the pad.

Accordingly, at least one embodiment can reduce the effective areas of the lower metal layers so that the capacitance from the pads may be reduced while also reducing the resistance of the pad. The exemplary embodiment can reduce or eliminate signal distortion and/or the occurrence of signal extinguishing, particularly for short pulse signals or high frequency signals.

For example, an exemplary embodiment is directed to a low loading pad for a Spin Transfer Torque Magnetoresistive Random Access Memory (STT-MRAM) bit cell. The low loading pad includes a plurality of hollow-shaped lower metal layers, and a top metal layer formed on an uppermost layer of the plurality of hollow-shaped lower metal layers.

In another embodiment, a low loading pad for a Spin Transfer Torque Magnetoresistive Random Access Memory (STT-MRAM) bit cell includes a plurality of lower metal layers, and a planar top metal layer formed on an uppermost layer of the plurality of lower metal layers. One of the plurality of lower metal layers is a hollow-shaped metal layer.

In yet another embodiment, a Spin Transfer Torque Magnetoresistive Random Access Memory (STT-MRAM) bit cell includes a low loading pad. The low loading pad includes a plurality of lower metal layers, and a planar top metal layer formed on an uppermost layer of the plurality of lower metal layers. One of the plurality of lower metal layers is a hollow-shaped metal layer.

Another exemplary embodiment is directed to a method of forming a low loading pad for a Spin Transfer Torque Magnetoresistive Random Access Memory (STT-MRAM) bit cell. The method includes forming a plurality of lower metal layers, and forming a planar top metal layer on an uppermost layer of the plurality of lower metal layers. One of the plurality of lower metal layers is a hollow-shaped metal layer.

### BRIEF DESCRIPTION OF THE DRAWINGS

The accompanying drawings are presented to aid in the description of embodiments of the invention and are provided solely for illustration of the embodiments and not limitation thereof.

FIG. 1 illustrates a conventional Spin Transfer Torque Magnetoresistive Random Access Memory (STT-MRAM) cell.

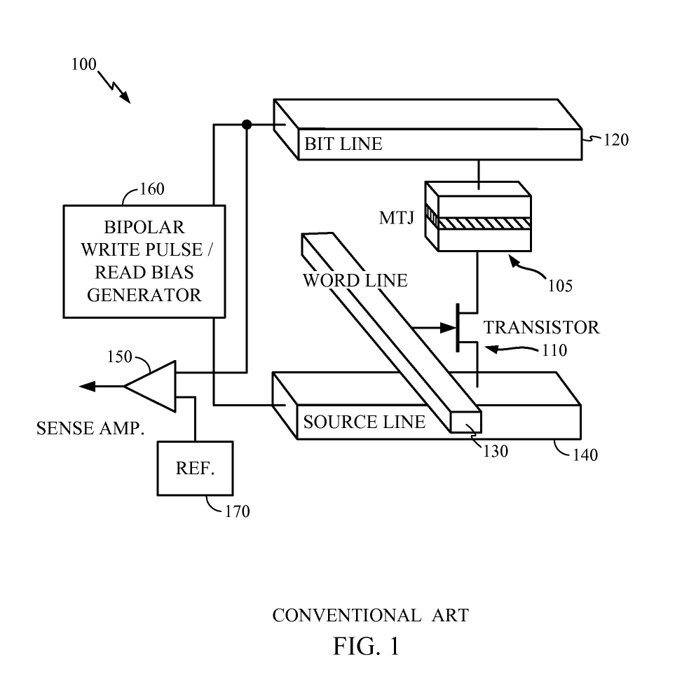

FIG. 2 is a side view of a pad according to an embodiment.

FIG. 3 is a top down view of a hollow-shaped lower metal layer of a pad according to an embodiment.

FIG. 4 is a top down view of a top metal layer and a hollow-shaped lower metal layer of a pad according to an embodiment.

FIG. 5 is an exploded, perspective view of a pad according to an embodiment.

FIG. 6 is another exploded, perspective view of a pad according to an embodiment.

FIG. 7 is a screen view of a top down view of a hollow-shaped lower metal layer of a pad according to an embodiment.

FIG. 8 is a screen view of a top down view of a top metal layer and a hollow-shaped lower metal layer of a pad according to an embodiment.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The words “exemplary” and/or “example” are used herein to mean “serving as an example, instance, or illustration.” Any embodiment described herein as “exemplary” and/or “example” is not necessarily to be construed as preferred or advantageous over other embodiments. Likewise, the term “embodiments of the invention” does not require that all embodiments of the invention include the discussed feature, advantage or mode of operation. Further, certain terminology, such as “on” (e.g., as in mounted ‘on’) and “substantially” are used in a broad manner herein. For example, the term “on” is intended to include, for example, an element or layer that is directly on another element or layer, but could alternatively include intervening layers between the elements/layers.

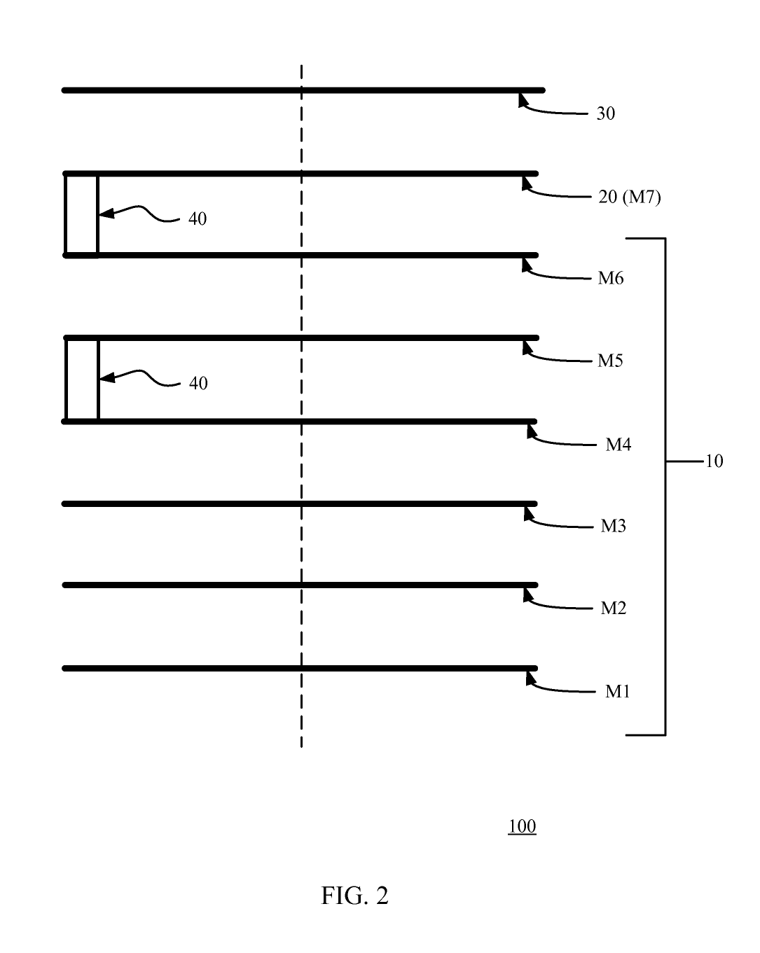

With reference to FIGS. 2-8, exemplary embodiments of structural designs of low loading pads for Magnetoresistive Random Access Memory (MRAM) bit cells, and more particularly, of low loading pads for Spin Transfer Torque Magnetoresistive Random Access Memory (STT-MRAM) bit cells, will now be described.

With reference to FIG. 2, an embodiment of a pad 100 can include a plurality of lower metal layers (e.g., metal layers M1 to M6) and a top metal layer (e.g., metal layer M7). In another embodiment, an additional metal layer, such as an aluminum (Al) layer 30, can be formed on the top metal layer 20. In this embodiment, the top metal layer 20 provides connectivity to the aluminum layer 30.

In an embodiment of the invention, the capacitance of the pad 100 can be reduced by removing or etching a portion (e.g., a majority) of one or more of the lower metal layers 10 (e.g., one or more of metal layers M1 to M6) to reduce the effective area of one or more of the lower metal layers 10 of the pad 100.

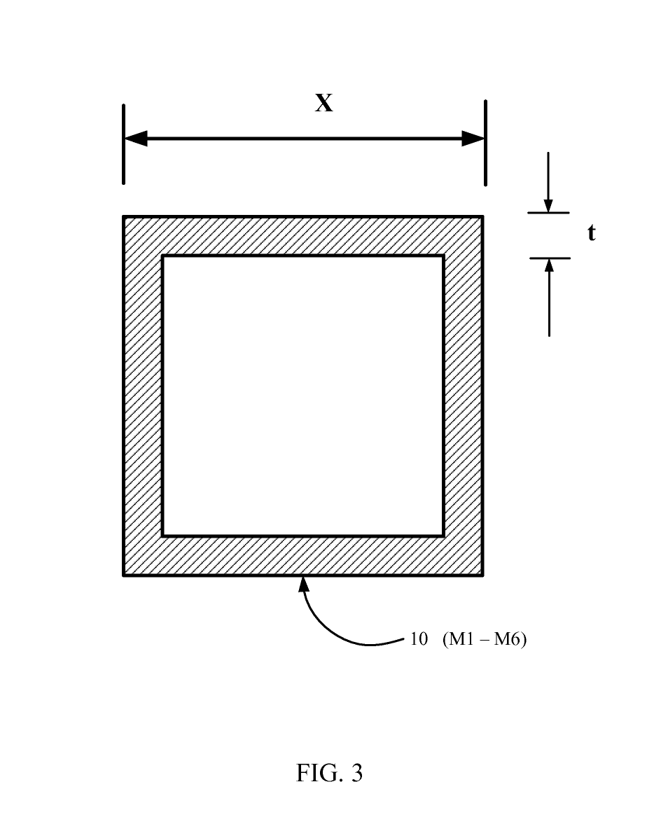

FIG. 3 shows an embodiment of a hollow-shaped lower metal layer 10 of a pad 100. The hollow-shaped lower metal layer 10 can form one or more of the lower metal layers M1 to M6 of a pad 100, for example, of a STT-MRAM bit cell. One of ordinary skill in the art will recognize that the lower metal layer 10 can be formed to be hollow-shaped according to various conventional techniques. The embodiments are not limited to etching or removing the lower metal layers 10 to form the hollow-shaped layer.

In FIG. 3, the lower metal layer 10 (e.g., one or more of metal layers M1 to M6) is exemplarily illustrated as being square shaped with a width X and a thickness t. For example, an exemplary lower metal layer 10 can be 90 μm×90 μm, with a thickness t=10 μm. However, the width X and/or thickness t of the lower metal layer 10 can be made smaller or larger. For example, in designing a pad 100, the thickness t of one or more of the lower metal layers 10 can be selected to reduce the capacitance of the pad 100 while also reducing the resistance. Also, the pad can be rectangular-shaped (e.g., square-shaped).

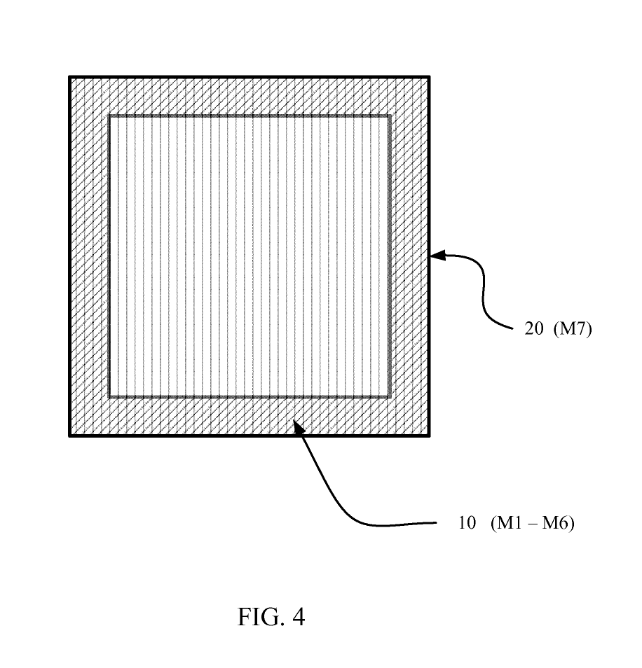

FIG. 4 is a top down view of a top metal layer 20 formed over a hollow-shaped lower metal layer 10 of a pad 100 according to an embodiment.

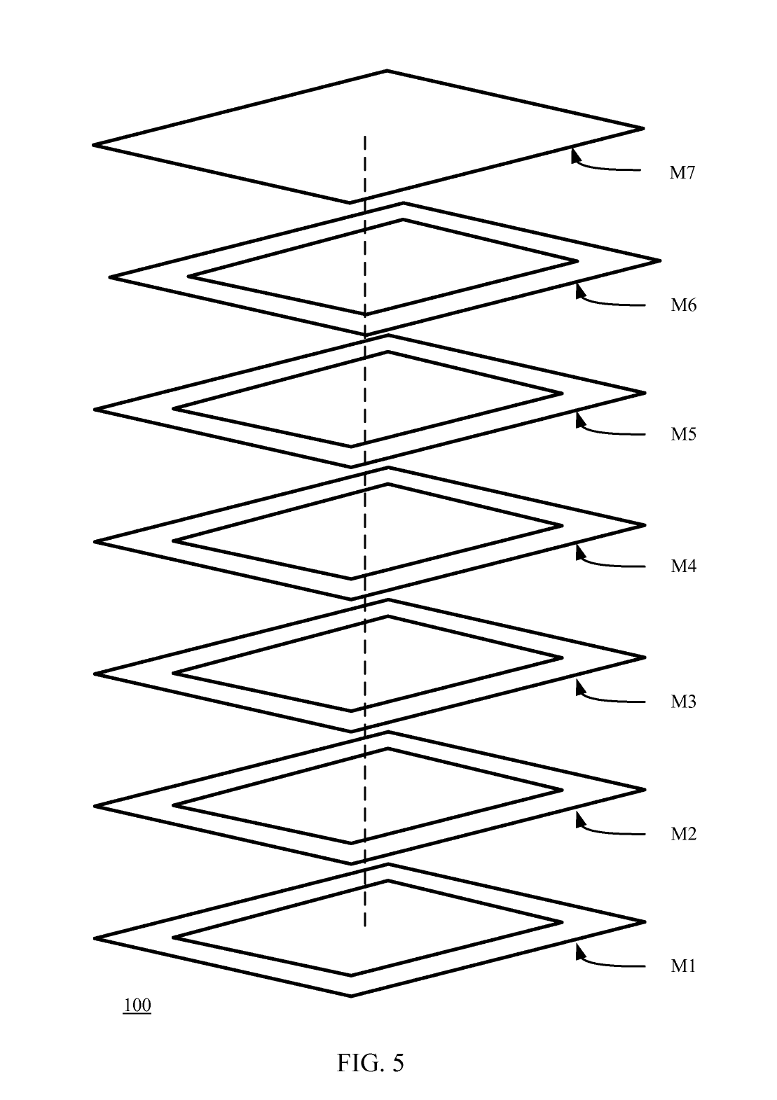

FIG. 5 is an exploded, perspective view of an embodiment of a pad 100 including a top metal layer 20 (e.g., metal layer M7) formed over the lower metal layers 10 (e.g., M1 to M6). The top metal layer 20 is a plate metal, for example, to facilitate wiring bonding to the pad 100. Thus, the parasitic capacitance of the pad 100 can be reduced by removing a portion of one or more of the lower metal layers 10 (e.g., metal layers M1-M6) up to the next to the top (e.g., second from the top) metal layer. For example, in the embodiment shown in FIG. 5, a center or central portion of each of the lower metal layers 10 (e.g., metal layers M1-M6) is removed to reduce the effective area of the lower metal layers 10 of the pad 100. By maintaining the edge or hollow-shaped portion of the lower metal layers 10, the novel pad 100 permits wire bounding at any location around the perimeter of the pad 100.

One of ordinary skill in the art will recognize that less than all of the lower metal layers 10 can have portions removed. Also, the amount of metal removed from each of the lower metal layers 10 can be different from layer to layer, or removed from different locations from layer to layer.

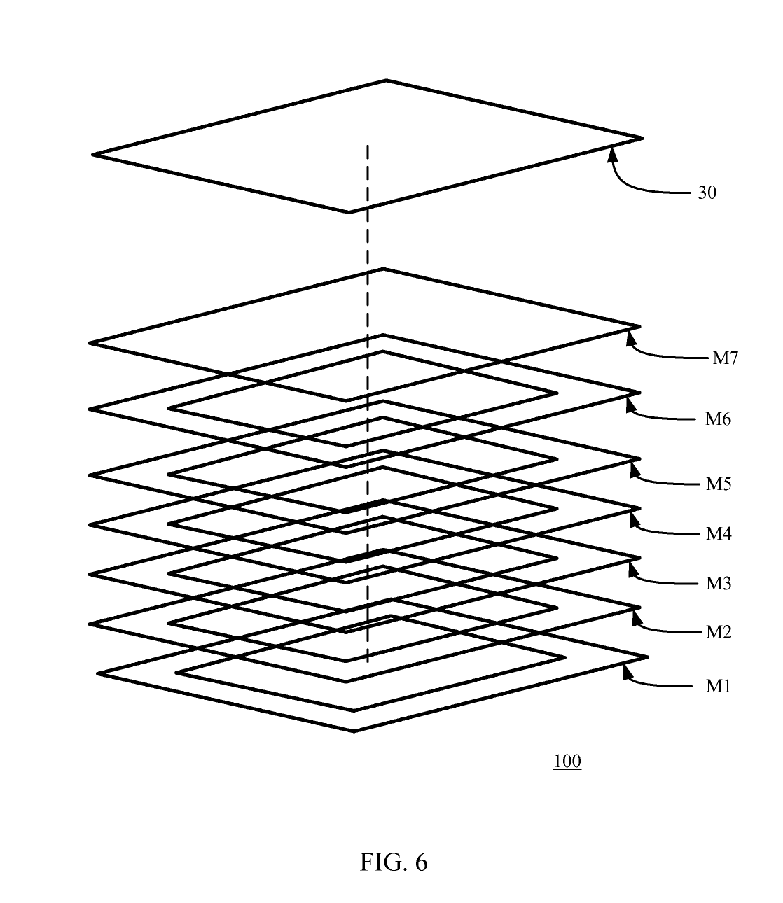

FIG. 6 illustrates an embodiment of a pad 100 including a top metal layer 20 (e.g., metal layer M7) and an aluminum (Al) layer 30, which are formed over the lower metal layers 10 (e.g., M1 to M6). The top metal layer 20 provides connectivity to the aluminum layer 30. Thus, the top metal layer 20 is formed to be a plate metal (e.g., a planar shape), instead of hollow-shaped. The aluminum layer 30 is formed over the top metal layer 20. The aluminum layer 30 is a plate metal, for example, to facilitate wiring bonding to the pad 100.

Referring again to FIG. 2, according to another embodiment, one or more via interconnects 40 are provided, for example, to connect the lower metal layers 10 (e.g., M1 to M6) to each other, or to connect the uppermost lower layer 10 (e.g., M6) to the top metal layer 20. The via interconnects 40 are moved to be edge via interconnects to provide a connection between the hollow-shaped metal layers 10, as exemplarily shown in FIG. 2. One of ordinary skill in the art will recognize that the via interconnects 40 can be formed at any location around the hollow-shaped layer. Also, the location of each respective via interconnect 40 around the perimeter of each metal layer can be the same or different from layer to layer.

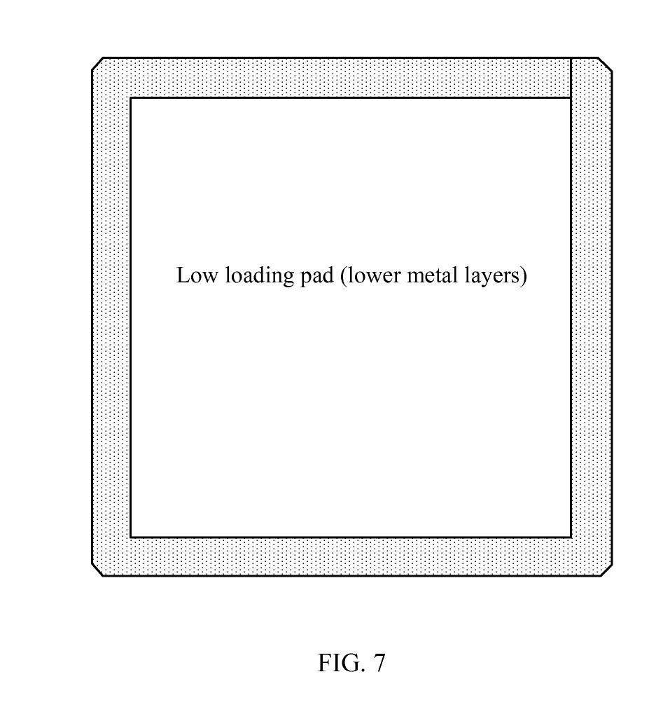

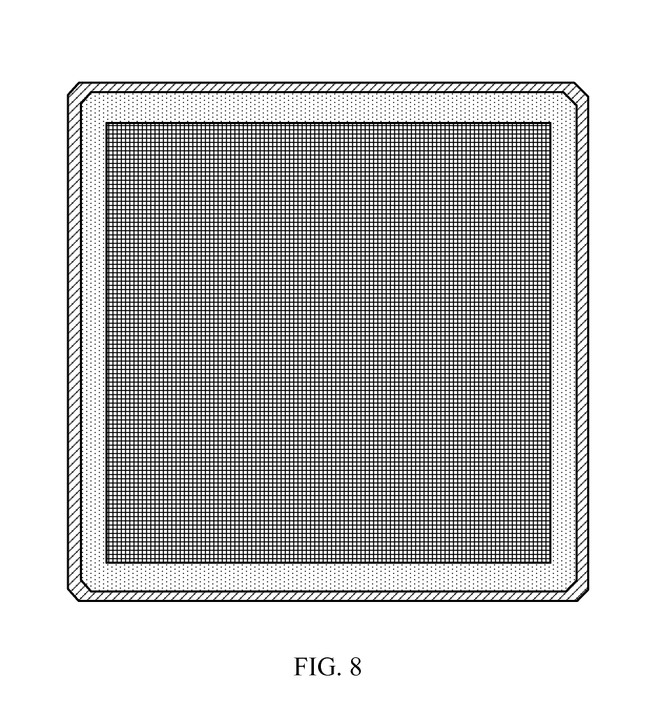

FIG. 7 is a screen view of a top down view of a hollow-shaped lower metal layer of a pad according to an embodiment. FIG. 8 is a screen view of a top down view of a top metal layer and a hollow-shaped lower metal layer of a pad according to an embodiment.

As shown in FIGS. 7 and 8, in an example, a pad for a STT-MRAM bit cell includes one or more hollow-shaped lower metal layers and a top metal layer formed over the lower metal layers.

Accordingly, the exemplary embodiments can reduce the capacitance of a pad 100 of, for example, a STT-MRAM bit cell, by removing or etching a portion (e.g., a majority) of one or more of the lower metal layers 10 (e.g., one or more of metal layers M1 to M6) to reduce the effective area of one or more of the lower metal layers 10 of the pad 100. In designing the pad 100, the thickness t of one or more of the lower metal layers 10 can be selected to reduce the capacitance of the pad 100 while also minimizing the resistance. The exemplary embodiment can reduce or eliminate signal distortion and/or the occurrence of signal extinguishing, particularly for short pulse signals or high frequency signals.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A low loading pad for a Spin Transfer Torque Magnetoresistive Random Access Memory (STT-MRAM) bit cell, the low loading pad comprising:
a plurality of hollow-shaped lower metal layers; and
a top metal layer formed on an uppermost layer of the plurality of hollow-shaped lower metal layers.

2. The low loading pad of claim 1, further comprising:
a via interconnect connecting two of the plurality of hollow-shaped lower metal layers,
wherein the via interconnect is disposed along a perimeter of the pad.

3. The low loading pad of claim 1, further comprising:
a via interconnect connecting the uppermost layer of the plurality of hollow-shaped lower metal layers and the top metal layer.

4. The low loading pad of claim 1, further comprising:
a plurality of via interconnects connecting two of the plurality of hollow-shaped lower metal layers,
wherein the plurality of via interconnects are disposed around a perimeter of the pad.

5. The low loading pad of claim 1, further comprising:
a plurality of via interconnects connecting the uppermost layer of the plurality of hollow-shaped lower metal layers and the top metal layer.

6. The low loading pad of claim 1, further comprising:
an aluminum layer formed over the top metal layer.

7. The low loading pad of claim 1, further comprising:
an aluminum layer formed over the top metal layer,
wherein the top metal layer is a solid layer.

8. The low loading pad of claim 1, wherein a capacitance of the plurality of hollow-shaped lower metal layers is less than a capacitance of the top metal layer.

9. The low loading pad of claim 1, wherein a perimeter of the plurality of hollow-shaped lower metal layers substantially corresponds to a perimeter of the top metal layer.

10. The low loading pad of claim 1, wherein a perimeter of the aluminum layer substantially corresponds to a perimeter of the top metal layer.

11. A low loading pad for a Spin Transfer Torque Magnetoresistive Random Access Memory (STT-MRAM) bit cell, the low loading pad comprising:
a plurality of lower metal layers; and
a planar top metal layer formed on an uppermost layer of the plurality of lower metal layers,
wherein one of the plurality of lower metal layers is a hollow-shaped metal layer.

12. The low loading pad of claim 11, wherein each of the plurality of lower metal layers is a hollow-shaped metal layer.

13. A Spin Transfer Torque Magnetoresistive Random Access Memory (STT-MRAM) bit cell comprising:
a low loading pad, wherein the low loading pad includes:
a plurality of lower metal layers; and
a planar top metal layer formed on an uppermost layer of the plurality of lower metal layers,
wherein one of the plurality of lower metal layers is a hollow-shaped metal layer.

14. The STT-MRAM bit cell of claim 13, wherein each of the plurality of lower metal layers is a hollow-shaped metal layer.

15. The STT-MRAM bit cell of claim 13, wherein the low loading pad further includes:
an aluminum layer formed over the planar top metal layer.

16. The STT-MRAM bit cell of claim 13, wherein the low loading pad further includes:
an aluminum layer formed over the planar top metal layer,
wherein the planar top metal layer is a solid layer.

17. The STT-MRAM bit cell of claim 13, wherein a capacitance of the plurality of lower metal layers is less than a capacitance of the planar top metal layer.

18. The STT-MRAM bit cell of claim 13, wherein a perimeter of the plurality of lower metal layers substantially corresponds to a perimeter of the planar top metal layer.

19. The STT-MRAM bit cell of claim 15, wherein a perimeter of the aluminum layer substantially corresponds to a perimeter of the planar top metal layer.

20. The STT-MRAM bit cell of claim 13, wherein the low loading pad further includes:
a via interconnect connecting two of the plurality of lower metal layers,
wherein the via interconnect is disposed along a perimeter of the pad.

21. The STT-MRAM bit cell of claim 13, wherein the low loading pad further includes:
a via interconnect connecting the uppermost layer of the plurality of lower metal layers and the planar top metal layer.

22. The STT-MRAM bit cell of claim 13, wherein the low loading pad further includes:
a plurality of via interconnects connecting two of the plurality of lower metal layers,
wherein the plurality of via interconnects are disposed around a perimeter of the pad.

23. The STT-MRAM bit cell of claim 13, wherein the low loading pad further includes:
a plurality of via interconnects connecting the uppermost layer of the plurality of lower metal layers and the planar top metal layer.

24. A method of forming a low loading pad for a Spin Transfer Torque Magnetoresistive Random Access Memory (STT-MRAM) bit cell, the method comprising:
forming a plurality of lower metal layers; and
forming a planar top metal layer on an uppermost layer of the plurality of lower metal layers,
wherein one of the plurality of lower metal layers is a hollow-shaped metal layer.
